(19) United States
(12) Patent Application Publication
(10) Pub. No.: US 2019/0311962 A1
(43) Pub. Date: Oct. 10, 2019

(54) HETEROGENEOUS INTEGRATED CIRCUITS WITH INTEGRATED COVERS

(71) Applicant: BAE SYSTEMS Information and Electronic Systems Integration Inc., Nashua, NH (US)

(72) Inventor: Timothy M. DRESSER, Wilton, NH (US)

(21) Appl. No.: 15/949,159

(22) Filed: Apr. 10, 2018

(51) Int. Cl. H01L 23/10; H01L 23/552; H01L 23/48; H01L 23/04; H01L 23/538; H01L 23/00; H01L 21/56; H01L 23/31

(52) U.S. Cl. CPC H01L 23/10; H01L 23/315; H01L 23/481; H01L 23/04; H01L 23/5381; H01L 24/81; H01L 24/16; H01L 24/13; H01L 21/56; H01L 23/3135; H01L 2224/81815; H01L 2224/16225; H01L 2224/13025; H01L 2224/8113; H01L 2224/81132; H01L 23/552

(57) ABSTRACT

The system and method for a heterogeneous integrated circuit packaging method having an air-cavity lid to protect the active face of an integrated circuit, or other device, either active or passive, from the environment. The packaging is hermetic or near hermetic. In some examples, the cover provides electrical routing. In some examples, the cover also provides electromagnetic shielding. In some cases, an encapsulant and/or an overmoulding is provided to further protect the heterogeneous integrated circuit.

### STATEMENT OF GOVERNMENT INTEREST

This disclosure was made with United States Government support under Contract No. HR0011-15-C-0103 awarded by the Defense Advanced Research Projects Agency. The United States Government has certain rights in this disclosure.

### FIELD OF THE DISCLOSURE

The present disclosure relates to providing environmental and chemical protection for heterogeneous integrated circuits and more particularly to the use of a low cost encapsulation and over-molding process to complete the packaging of heterogeneous integrated circuits.

### BACKGROUND OF THE DISCLOSURE

It has been recognized that high frequency heterogeneous integrated circuits require special consideration when packaging. Typically, that is in the form of hermetic sealing, which also has drawbacks such as it is challenging to retain electrical performance while providing sufficient environmental protection and low thermal resistance (e.g., junction to package and junction to ambient). For non-hermetic options which are often used on bare die, chip and wire in metal multi-chip module (MCM), and plastic quad-flat no-lead (QFN) packages, they require thick on-die passivation, which limits high frequency electrical performance.

Wherefore it is an object of the present disclosure to overcome the above-mentioned shortcomings and drawbacks associated with the conventional hermetic and near hermetic packaging.

### SUMMARY OF THE DISCLOSURE

One aspect of the present disclosure is a method of making a heterogeneous integrated circuit with an integrated cover, comprising: providing a first integrated circuit having a substrate side and an electronic circuit side; providing a cover with an integral air cavity; bonding the cover to the electronic circuit side of the first integrated circuit via a bonding agent to form a hermetic or near-hermetic bond; providing a multilayer circuit board or a second integrated circuit; and bonding the substrate side of the first integrated circuit to the multilayer circuit board or second integrated circuit via heterogeneous interconnects, thereby forming a heterogeneous integrated circuit with an integrated cover.

One embodiment of the method of making a heterogeneous integrated circuit with an integrated cover is wherein the integral air cavity is etched into the cover. In some embodiments, the cover comprises glass.

In certain embodiments, the cover provides electrical routing. In some embodiments, the cover provides electrical shielding.

Another embodiment of the method of making a heterogeneous integrated circuit with an integrated cover is wherein the step of attaching the cover to the first integrated circuit further comprises the steps of: aligning the cover onto the first integrated circuit; and reflowing a final surface metal on the cover.

In certain embodiments, aligning the cover utilizes fiducials in the cover and the first integrated circuit.

In yet another embodiment, the method of making a heterogeneous integrated circuit with an integrated cover further comprises providing an encapsulant. In some cases, the method of making a heterogeneous integrated circuit with an integrated cover further comprises providing an overmold on top of the encapsulant.

In certain embodiments, the encapsulant has a low dielectric constant. In some cases, the overmold comprises a potting compound.

Another aspect of the present disclosure is a heterogeneous integrated circuit with an integrated cover, comprising: a heterogeneous integrated circuit; and a cover attached to a circuit side of the heterogeneous integrated circuit via a bonding agent, wherein the cover provides an air cavity and provides environmental protection to the circuit side of the heterogeneous integrated circuit via a hermetic or near hermetic bond.

One embodiment of the heterogeneous integrated circuit with an integrated cover is wherein the cover provides electrical routing.

Another embodiment of the heterogeneous integrated circuit with an integrated cover is wherein the cover provides electrical shielding.

In yet another embodiment, the heterogeneous integrated circuit comprises a multilayer circuit board attached to at least one monolithic integrated circuit.

In some cases, the heterogeneous integrated circuit with an integrated cover further comprises an encapsulant. In certain embodiments, the heterogeneous integrated circuit with an integrated cover further comprises an overmold on top of the encapsulant.

In still yet another embodiment, the encapsulant has a low dielectric constant and the overmold comprises a potting compound.

In some cases, the cover provides electrical interconnects to a next higher level assembly.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1 is a diagrammatic view of one embodiment of a heterogeneous integrated circuit with an integrated cover of the present disclosure.

FIG. 2 is a diagrammatic view of one embodiment of a heterogeneous integrated circuit with an electrically shielded integrated cover of the present disclosure.

FIG. 3 is a diagrammatic view of one embodiment of a heterogeneous integrated circuit with an integrated cover and a low RF loss over molding scheme of the present disclosure.

FIG. 4 is a diagrammatic view of one embodiment of a heterogeneous integrated circuit with an integrated cover of the present disclosure where the external electrical interface is thru the cover.

### DETAILED DESCRIPTION OF THE DISCLOSURE

It is understood that RADAR, communications, imaging and sensing systems, and the like, rely on a wide variety of microsystems devices and materials. These diverse devices and materials typically require different substrates and different processing technologies, preventing the integration of these devices into single fabrication process flows. Integration of these device technologies has historically occurred only at the chip-to-chip level, which introduces significant bandwidth and latency-related performance limitations, as well as increased size, weight, power, and packaging/assembly costs as compared to microsystems fully integrated on a single chip.

In the Diverse Accessible Heterogeneous Integration (DAHI) program, transistor-scale heterogeneous integration processes are being developed to intimately combine advanced compound semiconductor (CS) devices, as well as other emerging materials and devices, with high-density silicon complementary metal-oxide-semiconductor (CMOS) technology. Such integration increases the capabilities of high-performance microsystems. Some of the many microsystem devices and materials that may be integrated include: 1) silicon complementary metal-oxide-semiconductors (Si CMOS) for highly integrated analog and digital circuits; 2) gallium nitride (GaN) for high-power/high-voltage swing and low-noise amplifiers; 3) gallium arsenide (GaAs) and indium phosphide (InP) heterojunction bipolar transistors (HBT) and high-electron mobility transistors (HEMT) for high speed/high-dynamic-range/low-noise circuits; 4) antimonide-based compound semiconductors for high-speed, low-power electronics; 5) compound semiconductor optoelectronic devices for direct-bandgap photonic sources and detectors, as well as or silicon-based structures for modulators, waveguides, etc.; 6) microelectromechanical (MEMS) components for sensors, actuators and RF resonators; 7) thermal management structures, and the like.

Some superchips developed using the DAHI process may require air above them (e.g. chiplets with exposed air bridges); these can only be integrated into assemblies that provide sufficient mechanical and environmental protection. This mechanical and environmental protection is traditionally provided by hermetic metal and ceramic packages. These conventional methods are expensive and time consuming.

One embodiment of the present disclosure is a method of protecting these air bridges by using a low cost encapsulation and over-molding process to complete the packaging of these heterogeneous integrated circuits (ICs).

In one embodiment, the protection is provided via an etched glass lid that is attached to the top of a component, such as a chiplet, which ties together minuscule circuits no larger than a grain of sand to make microprocessors, memory, and other electronic components, or the like. In other embodiments, the lid is attached to the base of a superchip, or the like.

One benefit of the packaging of the present disclosure is enabling low-cost chip-scale packaging of components that would otherwise need to be in a hermetic or near-hermetic housing (e.g., metal and/or ceramic) that encompasses the entire device. In many applications there is a challenge to combine the performance of bare MMICs with the low cost of surface mount circuit boards. At higher frequencies (e.g., above 10 GHz) MMICs require air above the surface of the device (especially the gate of field effect transistors). Traditional plastic overmolded packaging cannot provide these air cavities. Even low-dielectric constant die coating is typically not enough. Hermetic metal and ceramic packages have traditionally provided these air cavities, but with higher procurement cost as well as significantly larger footprint. Some examples of plastic air-cavity packages exist, but few of these options qualify as chip-scale packaging and operate thru 40 GHz and beyond.

Fine and gross leak testing is used to determine the effectiveness of package seals in microelectronic packages. Damaged or defective seals and feedthroughs allow ambient air/water vapor to enter the internal cavity of the device which can result in internal corrosion leading to device failures. Hermeticity testing may be performed just after the sealing process, or during screening/qualification. Hermeticity testing can be performed in accordance with MIL-STD-883, Test Method 1014 for hybrids/microcircuits and MIL-STD-750 for 1071 for discrete semiconductor devices. For MIL-STD-883H, Test Method 1014.13 categorizes a “seal” and provides for equivalent standard leak rates (atm cc/s air) for volumes: 1) ≤0.01 cc: 5×10⁻⁸; 2) >0.01 and ≤0.5 cc: 1×10⁻⁷; and 3) >0.5 cc: 1×10⁻⁶. For MIL-STD-750E, Test Method 1071.9 categorizes a “hermetic seal” for equivalent standard leak rates (atm cc/s air) for volumes: 1) ≤0.002 cc: 5×10⁻¹⁰; 2) >0.002 and ≤0.05 cc: 1×10⁻⁹; 3) >0.02 and ≤0.5 cc: 5×10⁻⁹; and 4) >0.5 cc: 1×10⁻⁸.

It is understood that testing evaluates “exchange rates” or the amount of time it takes for a device to “ingest” some percentage of the atmosphere to which it is exposed. In some cases, a 50% exchange rate may be used. In some cases a 90% exchange rate may be used. In certain embodiments, the rate may be hours, days, or even years depending on the application. As used herein, “near-hermetic” means molecules of water or H₂S and the like may be blocked, but smaller diameter dry gases, e.g., hydrogen, helium, etc.; may be permitted to pass through the “seal.”

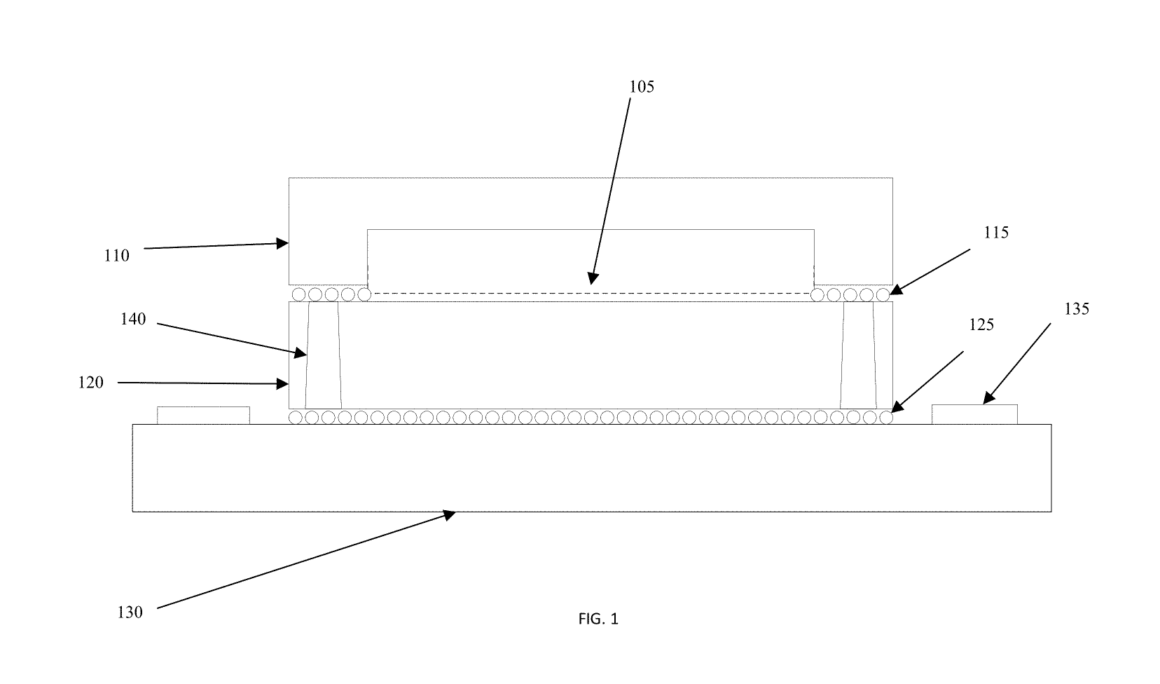

Referring to FIG. 1, a diagrammatic view of one embodiment of the present disclosure is shown. More specifically, an integrated environmental cover integrated into a heterogeneous integrated circuit is shown. In one embodiment, a lid 110 is assembled onto a first monolithic integrated circuit, or chiplet 120, which is assembled onto a second (often larger) integrated circuit, such as a superchip 130 or multilayer circuit board. The lid creates an air cavity 105 to protect the active face of device(s) on the chiplet. In certain embodiments, the lid 110 is bonded to the chiplet 120 via a bonding agent 115 and forms a hermetic or near-hermetic bond. In certain embodiments, the chiplet 120 is bonded to a multilayer circuit board 130, or superchip, via heterogeneous interconnects 125 or the like.

In some embodiments of the present disclosure, the bonding agents 115 are different depending on the application. In some cases, the bonding agent used to join the cover with the device can be, but is not limited to solder, polymer fusion, intermetallic bonding, epoxy and heterogeneous interconnects (similar to 125). In some cases, the bonding agent is AuSn solder. In certain embodiments, the circuit board 130 may have one or more interconnect metal layers 135 on the surface, and the two integrated circuits 120, 130 are connected using through substrate vias 140, or the like.

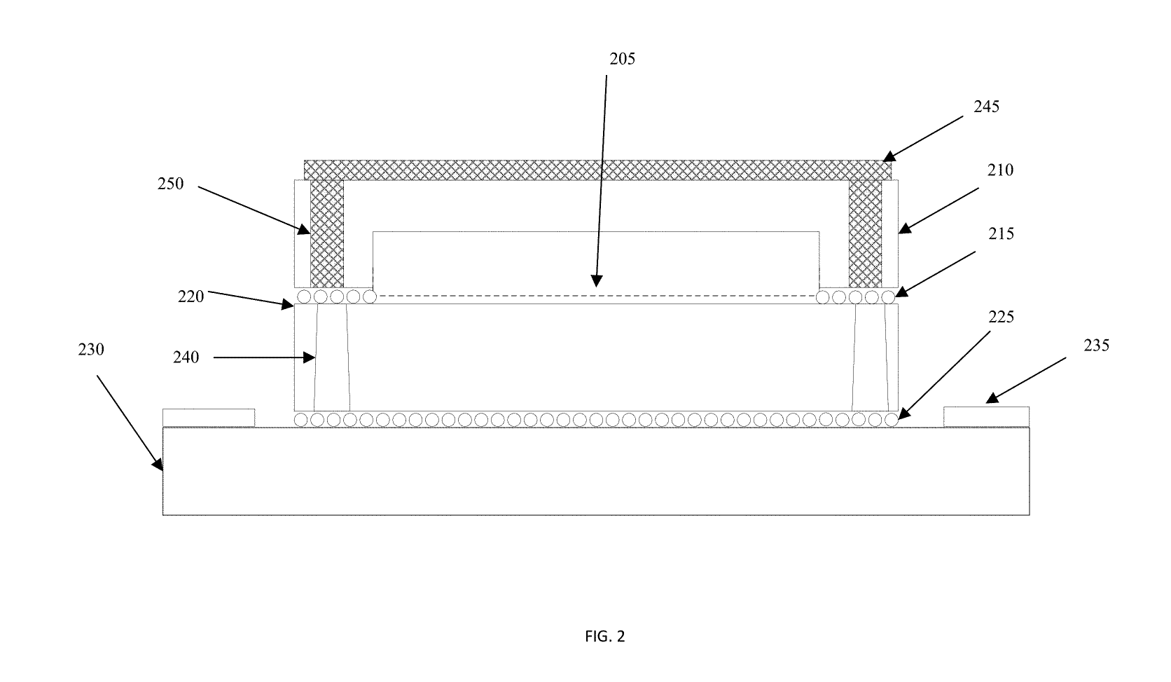

Referring to FIG. 2, a diagrammatic view of one embodiment of the present disclosure is shown. More specifically, an integrated environmental and electromagnetic shielding cover integrated into a heterogeneous integrated circuit is shown. In one embodiment, a lid 210 is assembled onto a monolithic integrated circuit, or chiplet 220, which is assembled onto another integrated circuit, or superchip 230, or multilayer circuit board. The lid creates an air cavity 205 to protect the active face of the device(s). In certain embodiments, the lid 210 is bonded to the chiplet 220 via a bonding agent 215 and forms a hermetic or near-hermetic bond. In certain embodiments, the chiplet 220 is bonded to a multilayer circuit board 230 via heterogeneous interconnects 225, or the like.

In certain embodiments of the present disclosure, the bonding agents 215 are different depending on the application. In some cases, the bonding agent used to join the cover with the device or chiplet, can be, but is not limited to solder, polymer fusion, intermetallic bonding, and epoxy. In some cases, the bonding agent is AuSn solder. In some cases, the circuit board or superchip 230 may have one or more interconnect metal layers 235 on the surface and the two integrated circuits 220, 230 are connected using through substrate vias 240, or the like.

Still referring to FIG. 2, electronic shielding 245 is incorporated into the lid and is further connected to the chiplet via through substrate vias (TSV) 250. In some cases, the circuit card side of the cover is a ball grid array (BGA) interface. It could also be a land grid array (LGA) or a quad-flat no-lead (QFN) compatible footprint. A land grid array (LGA) is a type of surface-mount packaging for integrated circuits (ICs) that is notable for having the pins on the socket (when a socket is used) rather than the integrated circuit.

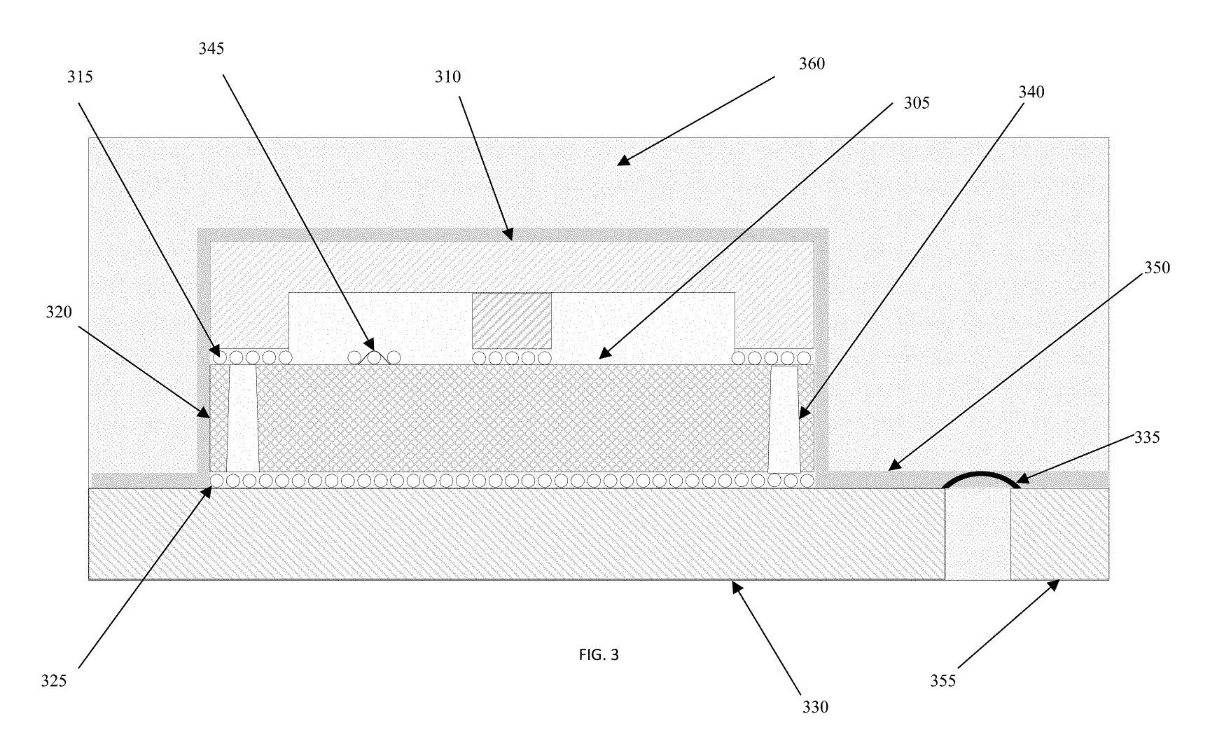

Referring to FIG. 3, a diagrammatic view of one embodiment of the present disclosure is shown. More specifically, an integrated cover integrated into a multichip assembly including dual stage over-molding is shown. This figure shows in detail a method of retaining RF performance with a low cost, non-low-loss encapsulant.

Still referring to FIG. 3, in one embodiment a lid 310 is assembled onto a monolithic integrated circuit, or chiplet 320, which is assembled onto another integrated circuit, or superchip 330, or multilayer circuit board. The lid creates one or more air cavities 305 to protect the active face of the device(s). In certain embodiments, the lid 310 is bonded to the chiplet 320 via a bonding agent 315 and forms a hermetic or near-hermetic bond. In certain embodiments, the chiplet 320 is bonded to a multilayer circuit board 330 via heterogeneous interconnects 325, or the like. In some cases, the heterogeneous interconnect interface 325 has a very fine pitch and is on the μm scale.

In certain embodiments of the present disclosure, the bonding agents 315 are different depending on the application. In some cases, the bonding agent used to join the cover with the device can be, but is not limited to solder, polymer fusion, intermetallic bonding, and epoxy. In some cases, the bonding agent is AuSn solder.

In some cases, the circuit board 330 may have one or more interconnect metal layers, or wire bonds 335 on the surface connecting the circuit board 330 to an adjacent substrate 355. Wire bonding is a method of making interconnections between an integrated circuit (IC) or other semiconductor device and its packaging. Although less common, wire bonding can also be used to connect an IC to other electronics or to connect from one printed circuit board (PCB) to another. In certain embodiments, the two integrated circuits 320, 330 are connected using through substrate vias 340, or the like.

In certain embodiments, a low RF impact encapsulant 350 is used to preserve RF signal trace and in some cases it has a low loss tangent. In some cases, the encapsulant has a low dielectric constant. In certain embodiments a bulk encapsulant 360 is used as an overmold. In certain embodiments, the overmold 360 provides for environmental protection against vibrations, shock, and the like. In some cases the overmold is a potting compound. In certain embodiments of the present disclosure, the lower layer of low-loss, low-dielectric 350 minimizes the impact of the over-molding 360 to the RF performance, while the upper layer 360 provides robust environmental protection without having to accommodate critical RF fields.

In certain embodiments, the encapsulant 350 is a low loss material where Er is ≤2 tan D≤0.01 and preferably ≤0.001. In some cases, silicones and other low loss dielectric polymers are likely candidate materials. In certain embodiments, the overmoulding 360 is selected for its mechanical characteristics, primarily CTE and robustness to mechanical damage, and an ability to survive in the end application environment. In some cases, traditional injection molding material and cast in place potting compounds are good candidate materials.

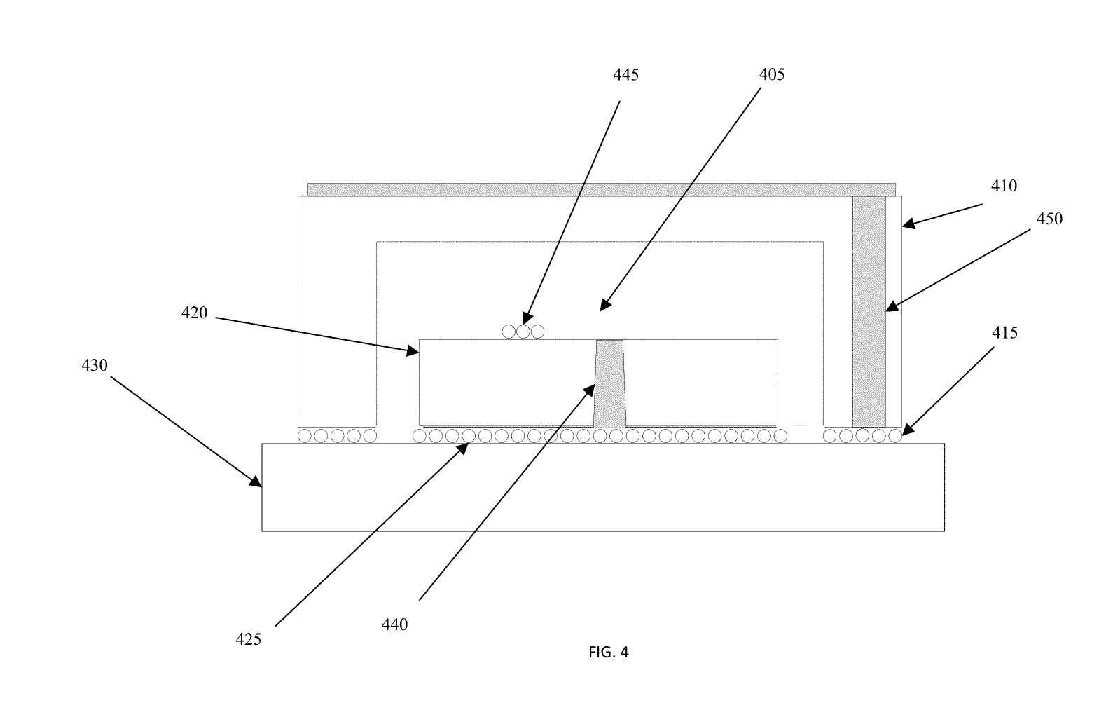

Referring to FIG. 4, a diagrammatic view of one embodiment of a heterogeneous integrated circuit with an integrated cover of the present disclosure where the external electrical interface is thru the cover is shown. More specifically, a lid 410 creates an interior air cavity 405 and is bonded to an integrated circuit 430 using a bonding agent 415. Another integrated circuit 420 is bonding to the integrated circuit 430 via heterogeneous interconnects 425 or the like.

In some cases, the circuit card side of the cover is a ball grid array (BGA) interface. It could also be a land grid array (LGA) or a quad-flat no-lead (QFN) compatible footprint. A land grid array (LGA) is a type of surface-mount packaging for integrated circuits (ICs) that is notable for having the pins on the socket (when a socket is used) rather than the integrated circuit. An LGA can be electrically connected to a printed circuit board (PCB) either by the use of a socket or by soldering directly to the board. Flat no-leads packages such as quad-flat no-leads (QFN) and dual-flat no-leads (DFN) physically and electrically connect integrated circuits to printed circuit boards. Flat no-leads, also known as micro leadframe (MLF) and SON (small-outline no leads), is a surface-mount technology. Flat no-lead is a near chip-scale plastic encapsulated package made with a planar copper lead frame substrate. Flat no-lead packages include an exposed thermal pad to improve heat transfer out of the integrated circuit (into the PCB). Heat transfer can be further facilitated by metal vias in the thermal pad. The QFN package is similar to the quad-flat package, and a ball grid array.

In some cases, a ball gate array (BGA) is used. A BGA is a type of surface-mount packaging (a chip carrier) used for integrated circuits. BGA packages are used to permanently mount devices such as microprocessors. A BGA can provide more interconnection pins than can be put on a dual in-line or flat package. The whole bottom surface of the device can be used, instead of just the perimeter. The leads are also on average shorter than with a perimeter-only type, leading to better performance at high speeds. In some cases, perimeter-only, or other methods may be used or even preferred depending on the application. Soldering of BGA devices requires precise control and is usually done by automated processes.

Still referring to FIG. 4, external electrical interface 450 is thru the cover 410. The active face of the device 445 is shielded via the cover 410 with a hermetic or near hermetic bond. The active face 445 is accessible to the integrated circuit 430 using through substrate vias 440 or the like. It is further understood that the lid can be connected to a monolithic circuit that may or may not be connected to one or more other monolithic circuits, printed circuit boards, or the like according to the principles of the present disclosure. In one embodiment of the cover electrical routing is provided through the cover. In some cases, the cover provides electrical shielding.

In certain embodiments, the lid or cover 110, 210, 310, 410 may be comprised of glass. Other versions of the lid could be, but are not limited to polymers, ceramics, and metals. In some cases, the lid is also transparent or translucent. The key requirements of the lids according to the principles of the present disclosure are providing sufficient hermeticity, compatible coefficient of thermal expansion (CTE) properties, and some form of thru substrate via interconnect thru lid for certain applications (e.g., FIG. 4).

In certain embodiments, the lid may be connected first to the chiplet, or the like, and then that assembly is connected to a superchip, or the like. In other cases, the chiplet may first be assembled onto the superchip, or the like, and then the lid is assembled onto the pre-joined integrated circuits. In many cases, the materials used as well as the particular bonding materials used in assembly will dictate the order of assembly for the various embodiments disclosed herein. In some cases, the gold interface on a monolithic microwave integrated circuit is adapted to a solder interface on a circuit board.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

1. A method of making a heterogeneous integrated circuit, comprising:
providing a first integrated circuit having a substrate side and an electronic circuit side;
providing a cover with an integral air cavity, the integral air cavity being etched into the cover;
bonding the cover with the integral air cavity to the electronic circuit side of the first integrated circuit via a bonding agent to form a hermetic or near-hermetic bond;
providing a second integrated circuit having a substrate side and an electronic circuit side;
bonding the substrate side of the first integrated circuit to the second integrated circuit via heterogeneous interconnects, wherein at least one of the first and second integrated circuits is a chiplet; and
providing an encapsulant over the cover and the first and second integrated circuits;
thereby forming a heterogeneous integrated circuit with a chiplet with an integrated cover, wherein the cover with the integrated air cavity provides electrical routing and protects the electronic circuit side or active face of the chiplet.

2. (canceled)

3. The method of making a heterogeneous integrated circuit with an integrated cover according to claim 1, wherein the cover comprises glass.

4. (canceled)

5. The method of making a heterogeneous integrated circuit with an integrated cover according to claim 1, wherein the cover provides electrical shielding.

6. The method of making a heterogeneous integrated circuit with an integrated cover according to claim 1, wherein the step of attaching the cover to the first integrated circuit further comprises the steps of:
aligning the cover onto the first integrated circuit; and
reflowing a final surface metal on the cover.

7. The method of making a heterogeneous integrated circuit with an integrated cover according to claim 6, wherein the aligning the cover utilizes fiducials in the cover and the first integrated circuit.

8. (canceled)

9. The method of making a heterogeneous integrated circuit with an integrated cover according to claim 1, further comprises providing an overmold on top of the encapsulant.

10. The method of making a heterogeneous integrated circuit with an integrated cover according to claim 1, wherein the encapsulant has a low dielectric constant.

11. The method of making a heterogeneous integrated circuit with an integrated cover according to claim 9, wherein the overmold comprises a potting compound.

12. A heterogeneous integrated circuit, comprising:
a first integrated circuit;
a second integrated circuit, wherein at least one of the first and the second integrated circuits is a chiplet;
a cover attached to a circuit side of the chiplet via a bonding agent, wherein the cover provides an air cavity, electrical routing, and provides environmental protection to the circuit side of the chiplet via a hermetic or near hermetic bond; and
an encapsulant over the cover and the first and second integrated circuits.

13. (canceled)

14. The heterogeneous integrated circuit with an integrated cover according to claim 12, wherein the cover provides electrical shielding.

15. The heterogeneous integrated circuit with an integrated cover according to claim 12, wherein the heterogeneous integrated circuit comprises a multilayer circuit board attached to at least one monolithic integrated circuit.

16. (canceled)

17. The heterogeneous integrated circuit with an integrated cover according to claim 12, further comprising an overmold on top of the encapsulant.

18. The heterogeneous integrated circuit with an integrated cover according to claim 12, wherein the encapsulant has a low dielectric constant.

19. The heterogeneous integrated circuit with an integrated cover according to claim 17, wherein the overmold comprises a potting compound.

20. The heterogeneous integrated circuit with an integrated cover according to claim 12, wherein the cover provides electrical interconnects to a next higher level assembly.
